(19) United States
(12) Patent Application Publication
(10) Pub. No.: US 2025/0243586 A1
(43) Pub. Date: Jul. 31, 2025

(54) ANTI-SCAVENGING HYDROGEN SULFIDE PROTECTIVE COATING FOR IMPROVED SUBTERRANEAN RESERVOIR SAMPLING

(71) Applicant: Schlumberger Technology Corporation, Sugar Land, TX (US)

(72) Inventors: Virendra Singh, Sugar Land, TX (US); Manuel Paul Marya, Sugar Land, TX (US)

(21) Appl. No.: 18/428,641

(22) Filed: Jan. 31, 2024

(51) Int. Cl. C23C 28/00

(52) U.S. Cl. CPC C23C 28/343

(57) ABSTRACT

Embodiments presented provide for the protection of field equipment deployed temporarily downhole and most importantly the non-scavenging of fluid species. In embodiments, an anti-scavenging hydrogen sulfide protective coating is provided to a subterranean reservoir fluid system for the protection of its surfaces with minimal interactions with the reservoir fluids to be collected and subsequently analyzed, particularly for hydrogen sulfide.

### CROSS-REFERENCE TO RELATED APPLICATIONS

None.

### FIELD OF THE DISCLOSURE

Aspects of the disclosure relate to thin coatings for the protection of field equipment and most importantly the anti-scavenging of fluid species. More specifically, aspects of the disclosure relate to the anti-scavenging of hydrogen sulfide by protective coatings used for downhole services, particularly fluid reservoir sampling systems and analyses.

### BACKGROUND

Hydrogen sulfide (H₂S), a corrosive and toxic compound commonly found in oil and gas reservoirs, can pose challenges during the extraction of oil or gas reservoir samples. When samples are collected from underground reservoirs-especially sour reservoirs (defined as reservoirs with hydrogen sulfide, or H₂S), the hydrogen sulfide can adsorb to the surfaces of both the flow tubing and reservoir sampling equipment and systems, including the sample bottles utilized for storage and transportation to the testing site. As a result, the measured levels of hydrogen sulfide can be inaccurately lower than the actual concentrations, thus under-reported. This under-reporting can have significant implications for well-infrastructure economics and equipment material selection. Additionally, the presence of H₂S can impact the regulatory compliance status of a site (for example, if the wellbore is identified as not sour, but is slightly sour). From an analysis standpoint, incorrect or incomplete information will also affect computational models used to understand reservoir behavior based on sample analysis.

The interaction of hydrogen sulfide with surfaces, where it is adsorbed, becomes more noticeable at lower concentrations, potentially leading to a substantial loss in concentration compared to the original sample. Such discrepancies in measured H₂S concentrations can be critical in determining compliance with regulatory and computational guidelines, which can also impact the safety of personnel, and the overall integrity of production and testing components. For instance, an error at 10 ppm levels of H₂S is often considered too high. For example, a concentration of 50 ppm at 10,000 psi pressure corresponds to an equivalent partial pressure of 0.5 psi, which is the minimum partial pressure for a fluid to be considered sour, whereas at a concentration of 40 ppm and 10,000 psi, the well would not be considered sour.

The capturing of reservoir samples typically occurs at the well site and involves subsequent analyses either in the field and/or at a testing facility. The various components within an oil and gas sample, along with their respective quantities, influence the choice of materials and equipment for processing the oil and gas. The adsorption of H₂S onto metal surfaces holds significance in gas purification, catalysis, and the oil industry in general. This adsorption process can occur through either chemisorption or physisorption. Hydrogen sulfide corrosion of oil and gas equipment can be prevented by inhibiting the interaction of H₂S on metal surfaces.

Due to the importance of maintaining hydrogen sulfide concentrations as close to those in the reservoir as possible, different inert non-scavenging surface coating(s) on testing equipment is required. These coatings create a physical barrier between the reservoir sample (oil & gas) and the underlying material, thus helping to prevent surface adsorption, given the inert nature of the coating itself.

Currently, many coatings are used to protect against H₂S corrosion, such as electroless nickel, weld overlay materials, and polymer-based coatings. These systems protect the base material by limiting reactions with H₂S and extending the life of the tools; however, they scavenge a small amount of H₂S. In other words, they react with H₂S and typically produce a superficial layer of sulfur compounds, such a nickel sulfide, iron sulfide or others.

For reservoir sampling applications, the interaction with even a small amount of H₂S with sampling systems (including bottle, tubing, fluid internal passageways, connectors) is important and may be unacceptable if the chemical concentration measurements is not maintained as close to the actual reservoir composition.

Using conventional materials, there is currently limited commercial solutions qualified as H₂S anti-scavenging coating. A conventional coating to reduce H₂S reactivity on metals involves a silica-based coating applied by chemical vapor deposition (CVD) at elevated temperatures, usually above 400° C. Such conventional coating has a limited wear resistance due to a very shallow thickness and relatively low hardness. These coatings can experience rapid damage during service, and thus over time do not guarantee the intended purpose of anti-scavenging H₂S. After multiple jobs, the effectiveness is lost. The conventional coating is also not effectively repairable at field locations, even in instance of a minor damage. The conventional coating is required to be fully removed and re-applied at the qualified location all over again, by placing the vessel back to elevated temperatures for extended time. This process, when repeated and cumulated can cause reduction in structural integrity (or mechanical properties) due to accumulated thermal cycles. Not only is structural integrity of the vessels can gradually be reduced by rework on used parts (as often needed), but the parts must be shipped back to limited worldwide suppliers and location available.

To date, diamond-like coatings (DLC) and polymer-like coatings (like DLC with typically with increased silicon) are not being used as H₂S anti-scavenging coatings. Some of the reported data are related to the corrosion protection provided by these coatings in a chloride environment; however, the use of these coatings for reservoir downhole applications in fluid sampling has not been reported and not known of.

There is a need to provide an apparatus and methods that are easy to operate and do not scavenge hydrogen sulfide like conventional apparatus and methods in the industry. Implicitly there is a need for a fully inert and impervious coating that will not remove H₂S from a measurement system, or alternatively may not be fully inert but should outperform the coating currently in use in the fields.

There is a further need to provide apparatus and methods that do not have the drawbacks discussed above, namely scavenging of important concentrations of hydrogen sulfide.

There is a still further need to reduce economic costs associated with operations and apparatus described above with conventional tools, to provide more cost-effective operations and analysis, for hydrocarbon recovery projects.

### SUMMARY

So that the manner in which the above recited features of the present disclosure can be understood in detail, a more particular description of the disclosure, briefly summarized below, may be had by reference to embodiments, some of which are illustrated in the drawings. It is to be noted that the drawings illustrate only typical embodiments of this disclosure and are therefore not to be considered limiting of its scope, for the disclosure may admit to other equally effective embodiments without specific recitation. Accordingly, the following summary provides just a few aspects of the description and should not be used to limit the described embodiments to a single concept.

In one example embodiment, a method for depositing an anti-scavenging coating is disclosed. The method may comprise obtaining a carrier tape with an anti-scavenging coating attached to the tape. The method may further comprise placing the coating in contact with a metal substrate that is intended to be covered by the anti-scavenging coating. The method may further comprise inducing placement of the anti-scavenging coating from the carrier tape to the metal substrate through activation of a laser on to the carrier tape.

In another example embodiment, an article of manufacture is disclosed. The article of manufacture may comprise a body made of a nickel-based alloy (or stainless steel). The article of manufacture may also comprise a coating placed upon at least a portion of the body, the coating having a first layer and a second layer, the first layer in contact with the body and the second layer in contact with the first layer, wherein one of the first layer and the second layer is a diamond-like carbon coating.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the drawings. It is to be noted; however, that the appended drawings illustrate only typical embodiments of this disclosure and are; therefore, not be considered limiting of its scope, for the disclosure may admit to other equally effective embodiments.

FIG. 1 is a cross-section for a sample cylinder used in downhole environments.

FIG. 2 is a cross-section of a gas sample cylinder used in downhole environments.

FIG. 3A is a cross-section of a piston rod used in downhole environments coated with a conventional coating.

FIG. 3B is a cross-section of a sample cylinder used in downhole environments coated with a conventional coating.

FIG. 3C is a cross-section of a ring used in downhole environments coated with a conventional coating.

FIG. 4 is a chart of values for conventional coatings.

FIG. 5A is a cross-section of a thin coating with two layers.

FIG. 5B is a graph of nano indentation data showing hardness.

FIG. 5C is a graph showing average friction coefficient.

FIG. 6 is a table showing performance of diamond like coating performance in corrosive environments.

FIG. 7A is a scanning electron microscope and analysis showing no sulfur detection on a surface after exposing sample 1 to 1.5 percent hydrogen sulfide corrosive conditions for 30 days for sample 1.

FIG. 7B is a scanning electron microscope picture and analysis showing no sulfur detection on a surface after exposing sample 1 to 1.5 percent hydrogen sulfide corrosive conditions for 30 days for sample 2.

FIG. 7C is a scanning electron microscope picture and analysis showing no sulfur detection on a surface after exposing sample 1 to 1.5 percent hydrogen sulfide corrosive conditions for 30 days for sample 4.

FIG. 7D is a scanning electron microscope picture and analysis showing no sulfur detection on a surface after exposing sample 1 to 1.5 percent hydrogen sulfide corrosive conditions for 30 days for sample 5.

FIG. 7E is a scanning electron microscope picture and analysis showing no sulfur detection on a surface after exposing sample 1 to 1.5 percent hydrogen sulfide corrosive conditions for 30 days for sample 6.

FIG. 8 is a diamond-like carbon coating with three layers in conformance with one example embodiment of the disclosure.

FIG. 9 is a schematic of a laser induced coating in one example embodiment of the disclosure.

FIG. 10 is a method in conformance with one example embodiment of the disclosure.

To facilitate understanding, identical reference numerals have been used, where possible, to designate identical elements that are common to the figures (“FIGS”). It is contemplated that elements disclosed in one embodiment may be beneficially utilized on other embodiments without specific recitation.

### DETAILED DESCRIPTION

In the following, reference is made to embodiments of the disclosure. It should be understood; however, that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments, and advantages are merely illustrative and are not considered elements or limitations of the claims except where explicitly recited in a claim. Likewise, reference to “the disclosure” shall not be construed as a generalization of inventive subject matter disclosed herein and should not be considered to be an element or limitation of the claims except where explicitly recited in a claim.

Although the terms first, second, third, etc., may be used herein to describe various elements, components, regions, layers and/or sections, these elements, components, regions, layers and/or sections should not be limited by these terms. These terms may be only used to distinguish one element, components, region, layer or section from another region, layer or section. Terms such as “first”, “second”, and other numerical terms, when used herein, do not imply a sequence or order unless clearly indicated by the context. Thus, a first element, component, region, layer, or section discussed herein could be termed a second element, component, region, layer, or section without departing from the teachings of the example embodiments.

When an element or layer is referred to as being “on,” “engaged to,” “connected to,” or “coupled to” another element or layer, it may be directly on, engaged, connected, coupled to the other element or layer, or interleaving elements or layers may be present. In contrast, when an element is referred to as being “directly on,” “directly engaged to,” “directly connected to,” or “directly coupled to” another element or layer, there may be no interleaving elements or layers present. Other words used to describe the relationship between elements should be interpreted in a like fashion. As used herein, the term “and/or” includes any and all combinations of one or more of the associated listed terms.

Some embodiments will now be described with reference to the figures. Like elements in the various figures will be referenced with like numbers for consistency. In the following description, numerous details are set forth to provide an understanding of various embodiments and/or features. It will be understood; however, by those skilled in the art, that some embodiments may be practiced without many of these details, and that numerous variations or modifications from the described embodiments are possible. As used herein, the terms “above” and “below”, “up” and “down”, “upper” and “lower”, “upwardly” and “downwardly”, and other like terms indicating relative positions above or below a given point are used in this description to more clearly describe certain embodiments.

Aspects of the disclosure apply to subterranean fluid samplers, surface transfer bottles, and other pressure vessels. These components may be used to sample fluids that contain hydrogen-sulfide. Aspects of the disclosure aim at improving upon existing surface protection technology, specifically inertness to H₂S. Disclosed in some embodiments is a barrier coating with one or more layers of carbon and/or silicon with oxygen, hydrogen, and misc. transition-element dopants, among diamond-like carbon (DLC) and Polymer-like carbon (PLC) films. In embodiments, useful coatings are a DLC layer first, deposited on a vessel wall with a superimposed PLC layer, for a total thickness between 500 nm to 5 micrometers. The coating not only protects the vessel wall against corrosion, but also reduces-if not fully prevent-H₂S scavenging, thereby enabling H₂S containing reservoir fluid collected downhole to be more accurately reported for subsequent analyses. The selected coatings may be characterized by a high hardness (>850 HVN) and low friction (<0.3) to offer extended life with sliding parts. By requirement, the coatings are applied below 250 degrees Celsius, to not influence vessel structural integrity (strength); e.g., by PE-CVD, PIID, and PVD-type processes. In other embodiments, a novel process (laser-induced PVD coating) is used wherein the desired coating is first applied to a CVD/PVD-deposited polymer (PET) transferred tape, and then later transferred onto the vessels through subsequent localized heating such as laser scans.

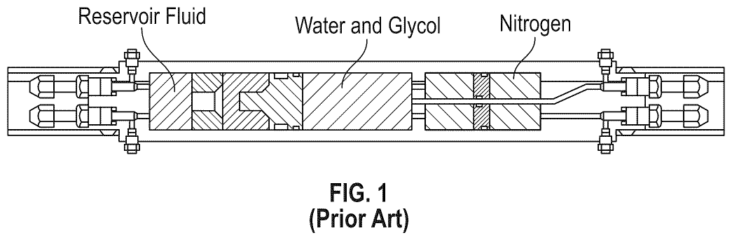

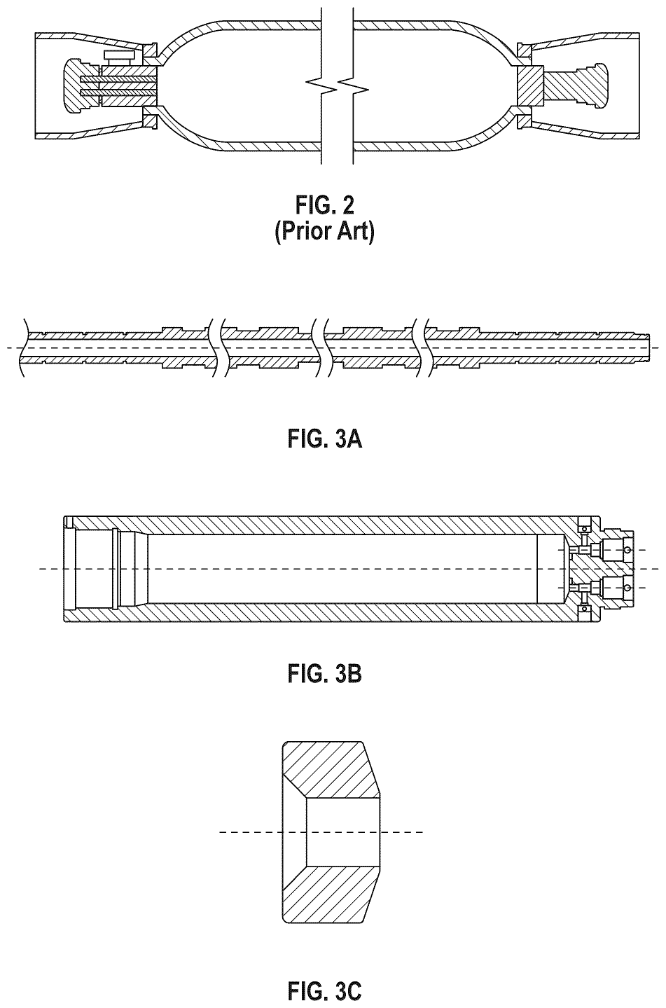

As will be understood, different components may be covered with the coating in whole or in part. For example, FIGS. 1 and 2 provide two different, but non-exclusive, components that may be used: FIG. 1 provides a sample cylinder for storage and transportation where the coating may be used; and FIG. 2 provides a gas sample bottle that may also be coated with different embodiments of the disclosure.

Aspects of the disclosure use processes suitable for low temperature deposition (<250 degrees Celsius) so as to not affect the mechanical properties (structural integrity) of the vessels; e.g., reservoir samplers. Some of the vessel materials that may be used include high-strength heat-treatable nickel-based alloys, cobalt-based alloys, titanium alloys, even aluminum alloys, where the cumulated exposure to conventional coating application temperatures can compromise the vessel structural integrity, including certifications, such as with DOT and ASME. Other types of materials may also be used, as long as proven reliable and compliant for holding reservoir fluids. In general, the materials of use include corrosion-resistant alloys (CRA) selected to be available at high-strength in diameters up to approximately 2 to 3 in. Typical corrosion-resistant materials, in use in general exhibit high-strength in excess of 120 ksi (827 MPa) and as high as 200 ksi (1378 MPa). Examples include UNS N07718, UNS N07625, UNS N07716, UNS N10276, and UNS N06022. The proposed coating process of aspects of this disclosure can be applied to both the internal and external diameter of cylindrical vessels, either directly in a physical vapor deposition (PVD) and chemical vapor deposition (CVD)-like coating chamber or, in some instances, with the parts serving as a coating chamber themselves.

In embodiments, a multilayer coating, such as a DLC coating, can exhibit wear (scratch) resistance, reduced friction, and H₂S non-scavenging property. The coating, when having minimal defects and some thickness, can typically withstand low and high pH level, as required by the applications, and provide competitive advantages over the coatings currently used for this purpose.

In aspects of the disclosure, the coating can be also applied by a laser induced PVD coating transfer method, to any metallic material. The laser induced PVD coatings offer the flexibility to selectively apply coatings to specific target surfaces, especially when there is physical damage to section of previous coating (e.g., loss of coating, scratch, dent). These coatings can be transferred using carrier tape and treated with laser technology. Laser-induced PVD coatings can be applied directly at well site remote locations. Referring to FIG. 3, conventional coatings may be used on different types of downhole apparatus, such as, a piston rod, as shown in FIG. 3A; a sample cylinder in FIG. 3B; and ring in FIG. 3C. All these applications may be provided by aspects of the disclosure.

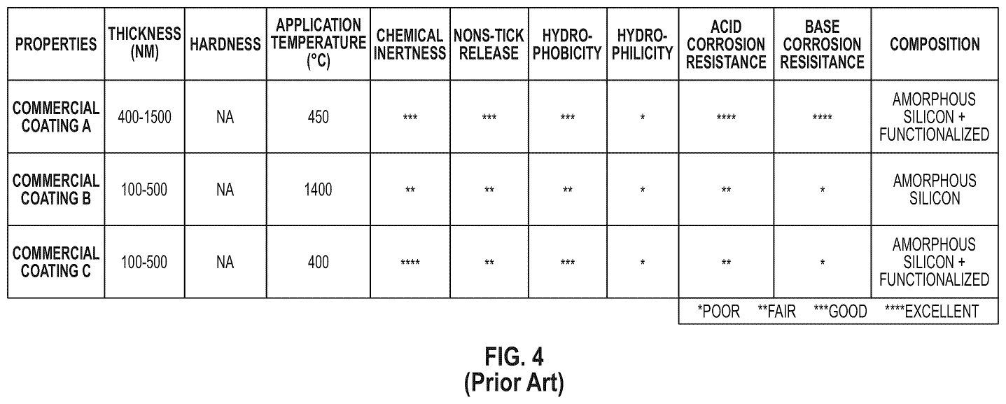

Referring to FIG. 4, a chart of values for conventional coatings used in protective applications is presented. Aspects of the current application show superior values to those shown in FIG. 4.

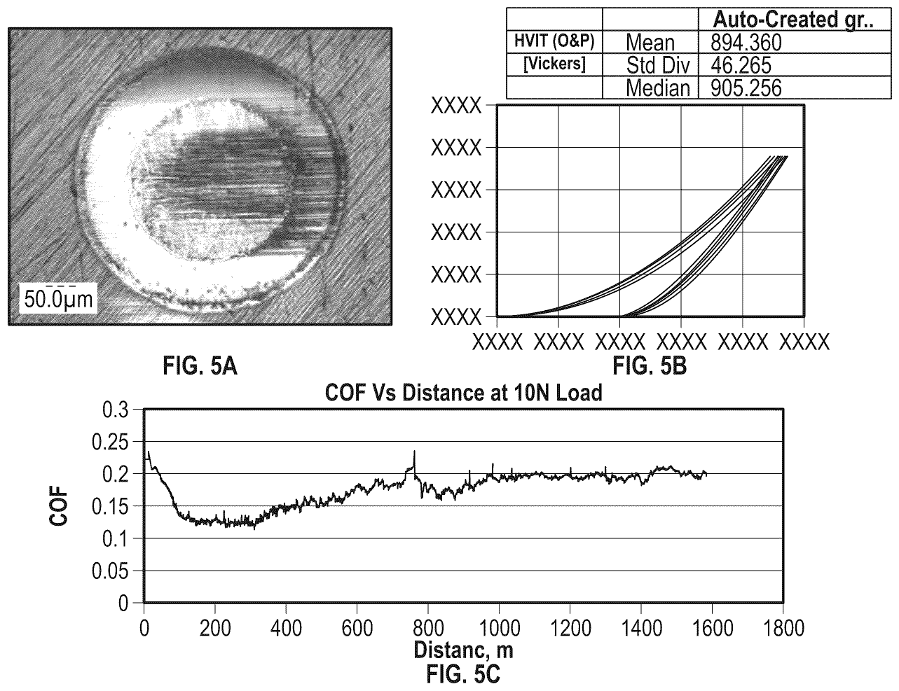

Newer diamond-like carbon (DLC) and polymer-like carbon (PLC) coating have evolved over the years and can now offer the proper replacement. Some internally developed and tested coatings show promise for H₂S scavenging and offer improved wear and friction properties, along with hydrophobic properties. These developed coatings are thin, from 400 nm to 5 microns and above, and can include multi-layered structures. FIG. 5 shows a 2-layer DLC coating. Thickness, hardness, and coefficient of friction are disclosed, all more favorable than conventional coatings and coating techniques for reservoir fluid sampling purposes. FIG. 5A is a cross-section of a thin coating with two layers, in accordance with one example embodiment of the disclosure. FIG. 5B is a picture of nano indentation data showing hardness. FIG. 5C is a graph showing an average friction coefficient.

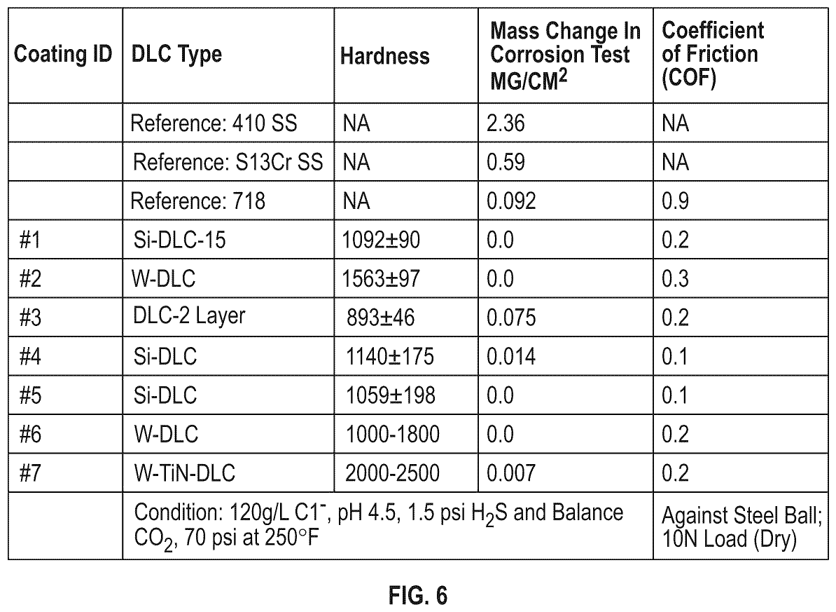

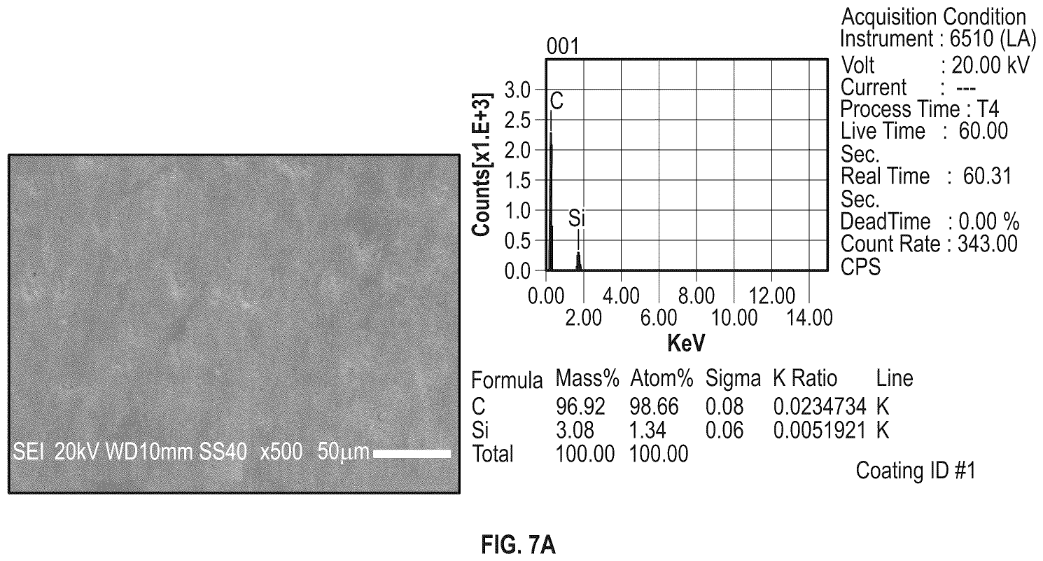

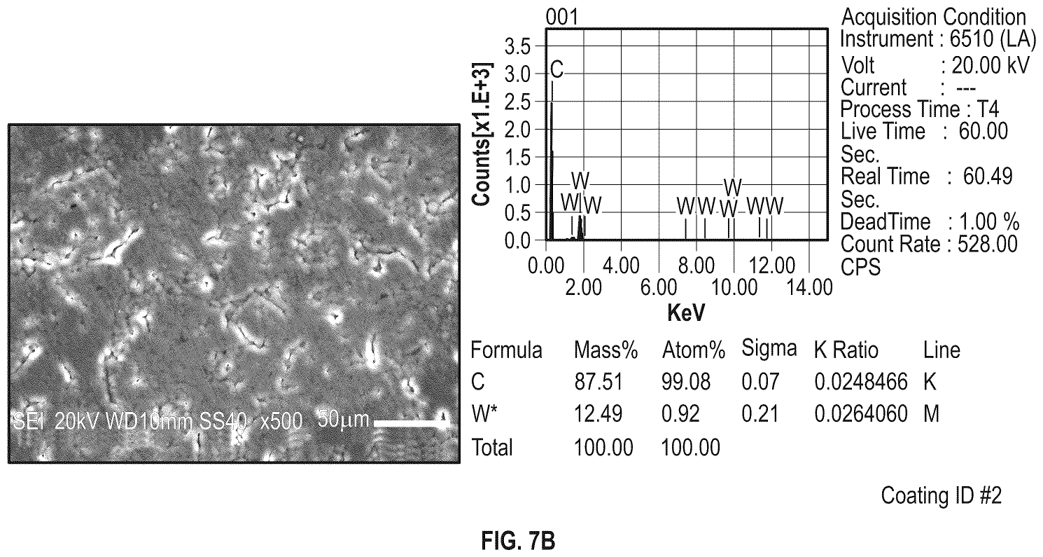

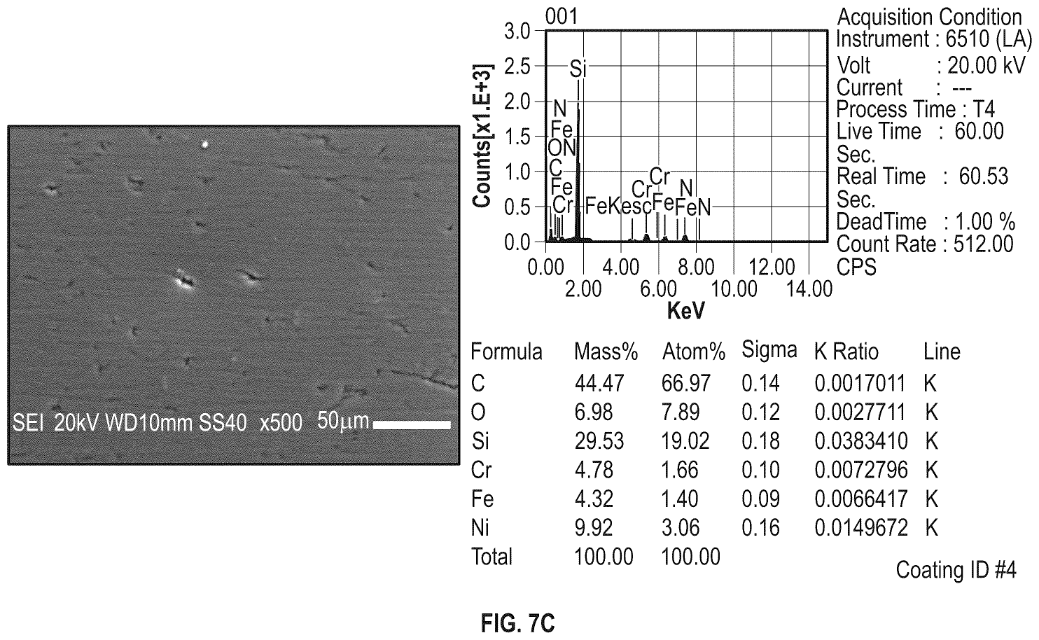

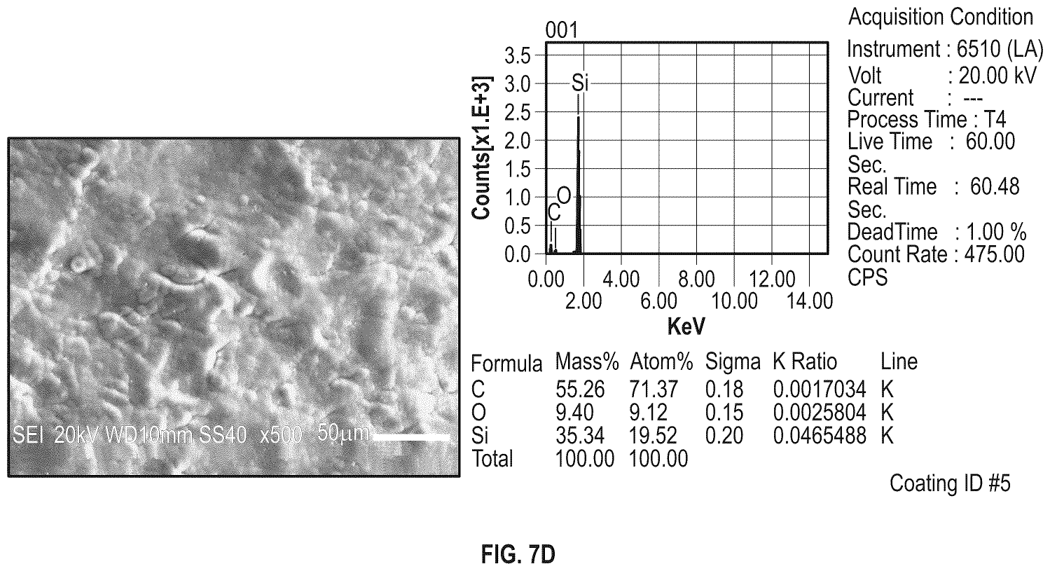

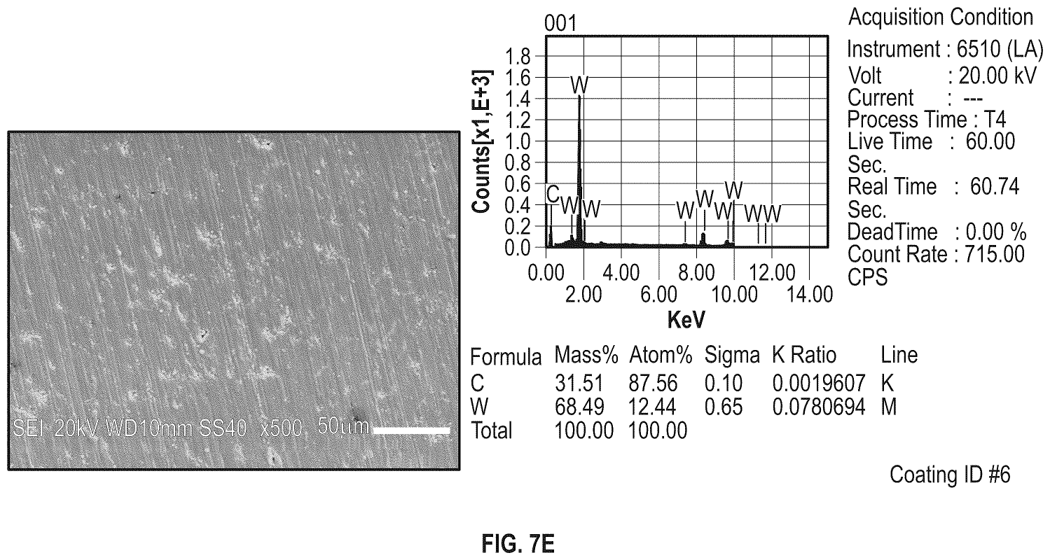

Referring to FIG. 6, a sample of different coatings used in embodiments of the disclosure are presented. Numbers with coating ID are different embodiments that should not be considered exhaustive. In embodiments, these coatings were also tested in different corrosive environments. The results show good performance in terms of mass loss. Some of the DLCs demonstrate inert characteristics in 30-day exposure to a corrosive environment containing H₂S. Results and data pertaining to various embodiments are shown in FIG. 7.

Referring to FIG. 7A, a depiction of a scanning electron microscope is presented. Analysis of data for this embodiment showing no sulfur detection on a surface after exposing sample 1 to 1.5 percent hydrogen sulfide corrosive conditions for 30 days for sample 1.

Referring to FIG. 7B, a depiction of a scanning electron microscope is presented. Analysis shows no sulfur detection on a surface after exposing sample 1 to 1.5 percent hydrogen sulfide corrosive conditions for 30 days for sample 2.

Referring to FIG. 7C, a depiction of a scanning electron microscope is presented. Analysis shows no sulfur detection on a surface after exposing sample 1 to 1.5 percent hydrogen sulfide corrosive conditions for 30 days for sample 4.

Referring to FIG. 7D, a depiction of a scanning electron microscope is presented. Analysis shows no sulfur detection on a surface after exposing sample 1 to 1.5 percent hydrogen sulfide corrosive conditions for 30 days for sample 5.

Referring to FIG. 7E, a depiction of a scanning electron microscope is presented. Analysis shows no sulfur detection on a surface after exposing sample 1 to 1.5 percent hydrogen sulfide corrosive conditions for 30 days for sample 6. As will be understood, different possibilities exist for materials to be incorporated into the various embodiments described above. In some embodiments, a high-strength nickel-alloy, such as Hastelloy™, Inconel™, titanium alloys, copper, copper alloys and aluminum alloys may be used. The coatings, when applied, may be applied at temperatures of less than 250 degrees Celsius for a processing time of 20 hours or less. In embodiments, a coating consists of at least two layers, including a layer of diamond-like carbon coating characterized by a total thickness between 500 nm to a maximum of 5 micrometers. In further embodiments, coatings may be doped to help different properties. Dopants may be, for example, silicon or tungsten and/or polymer like carbon rich materials in silicon, carbon and oxygen. In embodiments, the coating may be placed as a single layer on top of the diamond-like layer.

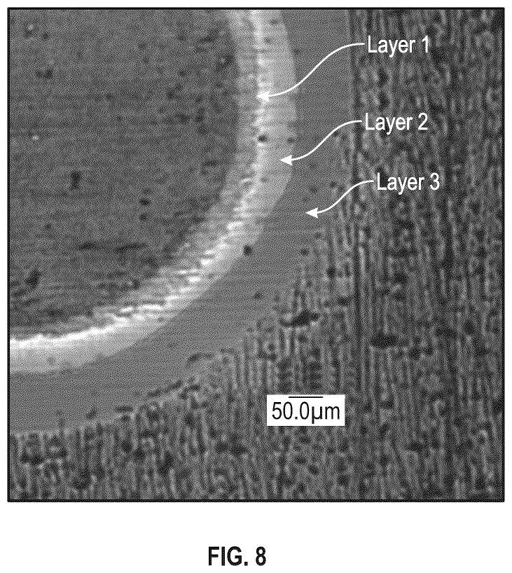

FIG. 8 is a depiction of a diamond-like carbon coating with three layers, in conformance with one example embodiment of the disclosure. As will be apparent, different numbers of layers of diamond-like coating may be used. In some instances, a single layer of diamond like coating is used. In some embodiments, greater numbers of layers may be used. In some embodiments, different types of layers other than diamond-like coatings may be used. Thus, a set of different types of layers may be used each for their properties.

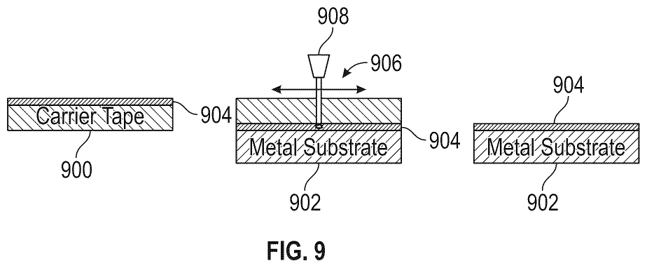

Referring to FIG. 9, a pictographic representation of a method for placing a coating on a surface is illustrated. A carrier tape 900 is presented as a medium for transferring materials onto a metal substrate 902. In the illustrated embodiment, a film 904, (e.g. a PVD film) is attached to the carrier tape 900. The entire assembly 906 of the carrier tape 900 and the film 904 is inverted and placed over the metal substrate 902. In the illustrated embodiment, it is desired that the film 904 is transferred to the metal substrate 902. In the middle portion of FIG. 9, while the assembly 906 is placed in contact with the metal substrate 902, a laser beam 908 is used to induce placement of the film 904 from the carrier tape 900 to the metal substrate 902. In this case, the laser beam may index back and forth over the desired coverage surface for the metal substrate 902. The result, as illustrated at the right of the figure, provides a metal substrate 902 with a desired coating of film 904 on the surface of the substrate 902.

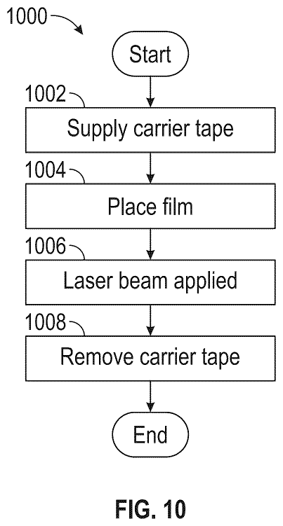

Referring to FIG. 10, a method 1000 for placement of a film on a metal substrate is illustrated. A carrier tape with an attached film is supplied at 1002. The method continues with placing the film in contact with a metal substrate to be covered at 1004. At 1006, a laser beam is used to induce the film from the carrier tape to the metal substrate. In embodiments, the laser beam may be indexed over a desired pattern thereby transferring the film onto desired portions of the metal substrate. At 1008, the carrier tape may removed producing a final product of a film coating desired areas of the metal substrate.

As will be understood, various alternative embodiments of the method described should be considered as possible alternatives. Both carbon-based and polymer-based coatings may be deposited on the carrier tape. The deposition of the carbon or polymer-based coatings may occur within a PVD physical vapor deposition process, PE-CVD plasma enhanced chemical vapor deposition process, or PIID process chamber, a plasma immersion ion dispersion process. As will be further understood, the depositing of the coating may be on a large continuous carrier tape, such as polyethylene terephthalate (PET) for roll-to-roll production. This may enable an onsite coating deposition on damaged service parts in a field setting.

Example embodiments of the claims are recited next. The recitation of these claims should not be considered limiting of the description. In one example embodiment, a method for depositing an anti-scavenging coating is disclosed. The method may comprise obtaining a carrier tape with an anti-scavenging coating attached to the tape. The method may further comprise placing the coating in contact with a metal substrate that is intended to be covered by the anti-scavenging coating. The method may further comprise inducing placement of the anti-scavenging coating from the carrier tape to the metal substrate through activation of a laser on to the carrier tape.

In another example embodiment, the method may be performed wherein the anti-scavenging coating is a carbon-based coating.

In another example embodiment, the method may be performed wherein the anti-scavenging coating is a polymer-based coating.

In another example embodiment, the method may be performed wherein the carrier tape with the anti-scavenging coating was manufactured by a physical vapor deposition process, a plasma enhanced chemical vapor deposition process, and a plasma immersion ion dispersion process.

In another example embodiment, the method may be performed wherein the carrier tape is made of polyethylene terephthalate.

In another example embodiment, an article of manufacture is disclosed. The article of manufacture may comprise a body made of a nickel alloy. The article of manufacture may also comprise a coating placed upon at least a portion of the body, the coating having a first layer and a second layer, the first layer in contact with the body, and the second layer in contact with the first layer, wherein one of the first layer and the second layer is a diamond-like coating.

In another example embodiment, the article of manufacture may be configured wherein a combined thickness of the first layer and the second layer is between approximately 500 nm to 5 micrometers.

In another example embodiment, the article of manufacture may be configured wherein at least one of the first layer and the second layer are doped with silicon.

In another example embodiment, the article of manufacture may be configured, wherein at least one of the first layer and the second layer are doped with tungsten.

In another example embodiment, the article of manufacture may be configured, wherein the second layer is a polymer-like coating.

In another example embodiment, the article of manufacture may be configured, wherein the second layer contains at least one of silicon, carbon, and oxygen.

In another example embodiment, the article of manufacture may be configured wherein the first and second layers have a coating hardness value over 800 HVN.

In another example embodiment, the article of manufacture may be configured wherein the first and second layers have a coating hardness value of less than 2500 HVN.

In another example embodiment, the article of manufacture may be configured wherein the second layer has a coating friction coefficient below 0.3.

In another example embodiment, the article of manufacture may be configured wherein the article is shaped as a pressure cylinder, a pressure chamber, a piston housing, a rod, a ring, a sample bottle, a sample chamber, and a bottle cylinder.

In another example embodiment, the article of manufacture may be configured wherein the article is used in a reservoir fluid analysis system.

In another example embodiment, the article of manufacture may be configured wherein the article has a 1-inch minimum internal diameter.

In another example embodiment, the article of manufacture may be configured wherein the article has a 40-inch length.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may be varied in many ways. Such variations are not to be regarded as a departure from the disclosure, and all such modifications are intended to be included within the scope of the disclosure.

While embodiments have been described herein, those skilled in the art, having benefit of this disclosure, will appreciate that other embodiments are envisioned that do not depart from the inventive scope. Accordingly, the scope of the present claims or any subsequent claims shall not be unduly limited by the description of the embodiments described herein.

What is claimed is:

1. A method for depositing an anti-scavenging coating, comprising:
obtaining a carrier tape with a sulfide anti-scavenging coating attached to the tape;
placing the coating in contact with a metal substrate that is intended to be covered by the sulfide anti-scavenging coating; and
inducing placement of the sulfide anti-scavenging coating from the carrier tape to fluid sampling system through activation of a laser on to the carrier tape.

2. The method according to claim 1, wherein the sulfide anti-scavenging coating is a carbon-based coating.

3. The method according to claim 1, wherein the sulfide anti-scavenging coating is a polymer-based carbon coating.

4. The method according to claim 1, wherein the carrier tape with the sulfide anti-scavenging coating was manufactured by a physical vapor deposition process, a plasma enhanced chemical vapor deposition process, and a plasma immersion ion dispersion process.

5. The method according to claim 1, wherein the carrier tape is made of polyethylene terephthalate.

6. An article of manufacture, comprising:
a body made of a corrosion-resistant alloy; and
a coating placed upon at least a portion of the body, the coating having a first layer and a second layer, the first layer in contact with the body and the second layer in contact with the first layer, wherein one of the first layer and the second layer is a diamond-like coating.

7. The article of manufacture according to claim 6, wherein a combined thickness of he first layer and the second layer is between approximately 500 nm to 5 micrometers.

8. The article of manufacture according to claim 6, wherein at least one of the first layer and the second layer are doped with silicon.

9. The article of manufacture according to claim 6, wherein at least one of the first layer and the second layer are doped with tungsten.

10. The article of manufacture according to claim 6, wherein the second layer is a polymer-like coating.

11. The article of manufacture according to claim 10, wherein the second layer contains at least one of silicon, carbon, and oxygen.

12. The article of manufacture according to claim 6, wherein the first and second layers have a coating hardness value over 800 HVN.

13. The article of manufacture according to claim 12, wherein the first and second layers have a coating hardness value of less than 2500 HVN.

14. The article of manufacture according to claim 6, wherein the second layer has a coating friction coefficient below 0.3.

15. The article of manufacture according to claim 6, wherein the article is shaped as a pressure cylinder, a pressure chamber, a piston housing, a rod, a ring, a sample bottle, a sample chamber, and a bottle cylinder.

16. The article of manufacture according to claim 6, wherein the article is used in a reservoir fluid analysis system.

17. The article of manufacture according to claim 6, wherein the article has a 1-inch minimum internal diameter.

18. The article of manufacture according to claim 6, wherein the article has a 40-inch length.
